(19) United States
(12) Patent Application Publication
(10) Pub. No.: US 2023/0097971 A1
(43) Pub. Date: Mar. 30, 2023

(54) METHOD OF MANUFACTURING WAVELENGTH CONVERTOR

(71) Applicant: SEIKO EPSON CORPORATION, Tokyo (JP)

(72) Inventors: Hideo MIYASAKA, Okaya-shi (JP); Yoko KANEMOTO, Suwa-gun Fujimi-machi (JP)

(21) Appl. No.: 17/953,465

(22) Filed: Sep. 27, 2022

(30) Foreign Application Priority Data
Sep. 29, 2021 (JP) 2021-158906

(51) Int. Cl. H01L 33/50; H01L 33/52; F21V 9/32

(52) U.S. Cl. CPC H01L 33/507; H01L 33/52; F21V 9/32

(57) ABSTRACT

Provided is a method including: preparing a substrate having a first surface; preparing a wavelength conversion layer that converts a light of a first wavelength band into a light of a second wavelength band different from the light of the first wavelength band; preparing a bonding material including a metal fine particle and a surface stabilizer formed at a surface of the metal fine particle and decomposed by oxygen; forming a protective film protecting the first surface while the protective film generates a gas containing hydrogen; releasing, from one of the protective film and the substrate, the gas occluded by the one of the protective film and the substrate in the forming of the protective film; and bonding the substrate and the wavelength conversion layer via the bonding material by metal sintering.

The present application is based on, and claims priority from JP Application Serial Number 2021-158906, filed Sep. 29, 2021, the disclosure of which is hereby incorporated by reference herein in its entirety.

### BACKGROUND

### 1. Technical Field

The present disclosure relates to a method of manufacturing a wavelength convertor.

### 2. Related Art

JP-A-2017-116719 discloses a method of bonding a substrate and a phosphor layer by sintering silver nanoparticles. WO 2014/065051 discloses a method of forming a nickel-phosphorus film (Ni—P film) functioning as a protective film layer and a gold (Au) film functioning as a solder wetting film layer on a surface of a substrate by a plating method.

For example, when a wavelength convertor is to be formed, the wavelength convertor can be formed by bonding the plated substrate described in WO 2014/065051 and a phosphor layer functioning as a wavelength conversion layer by the bonding method described in JP-A-2017-116719.

However, according to the methods of the above Patent Literatures, there is a problem that a bonding strength between the substrate and the phosphor layer is reduced due to a gas released by heating during bonding, foreign matter attached to a surface of a plating film when plating is performed, and the like, and thus the phosphor layer is easily peeled off from the substrate.

### SUMMARY

A method of manufacturing a wavelength convertor includes: preparing a substrate having a first surface; preparing a wavelength conversion layer that modulates a light of a first wavelength band into a light of a second wavelength band different from the light of the first wavelength band; preparing a bonding material including a metal fine particle and a first film formed at a surface of the metal fine particle and decomposed by oxygen; forming a protective film protecting the first surface while generating a gas containing hydrogen; releasing, from the protective film or the substrate, the gas occluded by the protective film or the substrate in the forming of the protective film; and bonding the substrate and the wavelength conversion layer via the bonding material by metal sintering.

A method of manufacturing a wavelength convertor includes: preparing a substrate having a first surface and a protective film containing a first substance for protecting the first surface; preparing a wavelength conversion layer that modulates a light of a first wavelength band into a light of a second wavelength band different from the light of the first wavelength band; preparing a bonding material containing a metal fine particle; removing, by plasma cleaning, foreign matter different from the first substance attached to a surface of the protective film opposite to the substrate; and bonding the substrate including the protective film and the wavelength conversion layer via the bonding material by metal sintering.

### BRIEF DESCRIPTION OF THE DRAWINGS

FIG. 1 is a schematic diagram showing a configuration of a projector.

FIG. 2 is a perspective view showing a configuration of a wavelength convertor.

FIG. 3 is a cross-sectional view taken along a line A-A′ of the wavelength convertor shown in FIG. 2.

FIG. 4 is a cross-sectional view showing a structure of a bonding material.

FIG. 5 is a cross-sectional view showing a configuration of the bonding material.

FIG. 6 is a cross-sectional view showing a configuration of the bonding material.

FIG. 7 is a flowchart showing a method of manufacturing a wavelength convertor according to a first embodiment.

FIG. 8 is a cross-sectional view showing the method of manufacturing the wavelength convertor.

FIG. 9 is a cross-sectional view showing the method of manufacturing the wavelength convertor.

FIG. 10 is a cross-sectional view showing the method of manufacturing the wavelength convertor.

FIG. 11 is a cross-sectional view showing the method of manufacturing the wavelength convertor.

FIG. 12 is a graph showing a relationship between the number of times of heating and a gas ion intensity.

FIG. 13 is a flowchart showing a method of manufacturing a wavelength convertor according to a second embodiment.

FIG. 14 is a diagram showing a state of a bonding material before and after treatment.

FIG. 15 is a graph showing a bonding ratio of the bonding material before and after the treatment.

FIG. 16 is a graph showing a neck thickness of the bonding material before and after the treatment.

### DESCRIPTION OF EXEMPLARY EMBODIMENTS

For convenience of description, an X axis, a Y axis, and a Z axis are shown in each figure as three axes orthogonal to each other. A direction parallel to the X axis is also referred to as an “X axis direction”, a direction parallel to the Y axis is also referred to as a “Y axis direction”, and a direction parallel to the Z axis is also referred to as a “Z axis direction”. The Z axis direction is along a vertical direction, and an XY plane is along a horizontal plane. An arrow tip side in each axis direction is also referred to as a “plus side”, and a base end side is also referred to as a “minus side”. The plus side in the Z axis direction is also referred to as “upper”, and the minus side in the Z axis direction is also referred to as “lower”.

Further, in the following description, for example, with respect to a substrate, the description “on a substrate” represents any one of a case where an object is disposed in contact with the substrate, a case where an object is disposed on the substrate via another structure, and a case where a part of an object is disposed in contact with the substrate and the other part thereof is disposed on the substrate via another structure.

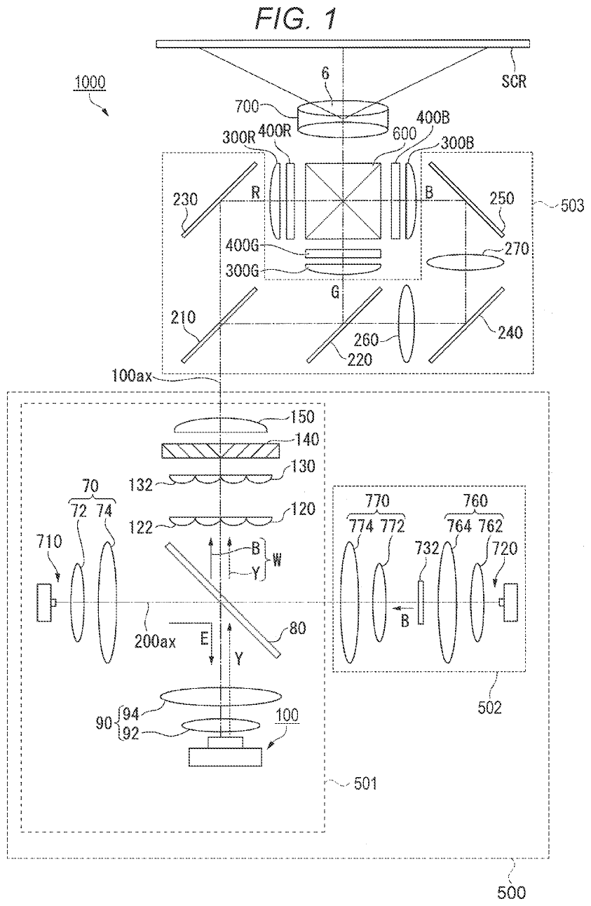

First, a configuration of a projector 1000 will be described with reference to FIG. 1.

As shown in FIG. 1, the projector 1000 includes a first illumination device 501, a second illumination device 502, a color separation light guiding optical system 503, a light modulation device 400R, a light modulation device 400G, a light modulation device 400B, a photosynthetic element 600, and a projection optical device 700, which are disposed in an exterior housing (not shown). The first illumination device 501 and the second illumination device 502 are collectively referred to as a light source device 500.

The first illumination device 501 includes a first light source 710, a collimating optical system 70, a dichroic mirror 80, a collimating and condensing optical system 90, a wavelength convertor 100, a first lens array 120, a second lens array 130, a polarization convertor 140, and a superimposing lens 150.

The first light source 710 is formed of a semiconductor laser that emits a blue excitation light E having a peak wavelength of emission intensity of, for example, 445 nm and a wavelength range of, for example, 440 nm to 450 nm in a first wavelength band. The first light source 710 may be formed of one semiconductor laser or may be formed of a plurality of semiconductor lasers.

The first light source 710 is disposed such that an optical axis 200ax of a laser light emitted from the first light source 710 is orthogonal to an illumination optical axis 100ax. The first light source 710 may be a semiconductor laser that emits an excitation light having a peak wavelength other than 445 nm, for example, a peak wavelength of 460 nm.

The collimating optical system 70 includes a first lens 72 and a second lens 74. The collimating optical system 70 substantially collimates the light emitted from the first light source 710. Each of the first lens 72 and the second lens 74 is formed of a convex lens.

The dichroic mirror 80 is disposed in a direction intersecting with each of the optical axis 200ax of the first light source 710 and the illumination optical axis 100ax at an angle of 45°, in an optical path from the collimating optical system 70 to the collimating and condensing optical system 90. The dichroic mirror 80 reflects the excitation light E. A yellow fluorescence Y including a red light component and a green light component is transmitted through the dichroic mirror 80.

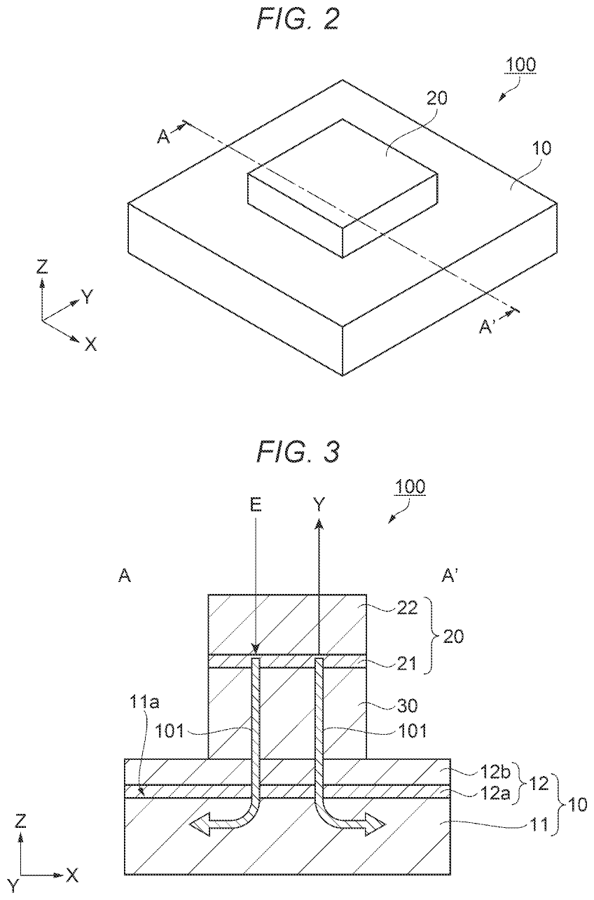

The collimating and condensing optical system 90 has a function of condensing the excitation light E transmitted through the dichroic mirror 80 and causing the excitation light E to be incident on a wavelength conversion layer 20 (see FIG. 2) of the wavelength convertor 100, and a function of substantially collimating the fluorescence Y emitted from the wavelength convertor 100. The collimating and condensing optical system 90 includes a first lens 92 and a second lens 94. Each of the first lens 92 and the second lens 94 is formed of a convex lens.

A specific configuration of the wavelength convertor 100 included in the first illumination device 501 will be described later with reference to FIGS. 2 and 3.

The second illumination device 502 includes a second light source 720, a condensing optical system 760, a diffuser plate 732, and a collimating optical system 770.

The second light source 720 is formed of the same semiconductor laser as the first light source 710 of the first illumination device 501. The second light source 720 may be formed of one semiconductor laser or may be formed of a plurality of semiconductor lasers. In addition, the second light source 720 may be formed of a semiconductor laser having a wavelength band different from that of the semiconductor laser of the first light source 710.

The condensing optical system 760 includes a first lens 762 and a second lens 764. The condensing optical system 760 condenses a blue light B emitted from the second light source 720 on a diffusion surface of the diffuser plate 732 or in the vicinity of the diffuser plate 732. The first lens 762 and the second lens 764 are formed of convex lenses.

The diffuser plate 732 diffuses the blue light B from the second light source 720 and generates the blue light B having a light distribution close to a light distribution of the fluorescence Y emitted from the wavelength convertor 100. As the diffuser plate 732, for example, polished glass made of optical glass can be used.

The collimating optical system 770 includes a first lens 772 and a second lens 774. The collimating optical system 770 substantially collimates the light emitted from the diffuser plate 732. Each of the first lens 772 and the second lens 774 is formed of a convex lens.

The blue light B emitted from the second illumination device 502 is reflected by the dichroic mirror 80, is synthesized with the fluorescence Y emitted from the wavelength convertor 100 and transmitted through the dichroic mirror 80, and becomes a white light W. The white light W is incident on the first lens array 120.

The first lens array 120 includes a plurality of first lenses 122 for dividing the light from the dichroic mirror 80 into a plurality of partial light fluxes. The plurality of first lenses 122 are arranged in a matrix in a plane orthogonal to the illumination optical axis 100ax.

The second lens array 130 includes a plurality of second lenses 132 corresponding to the plurality of first lenses 122 of the first lens array 120. The second lens array 130, together with the superimposing lens 150 in a subsequent stage, forms an image of each of the first lenses 122 forming the first lens array 120 in the vicinity of an image forming region of each of the light modulation device 400R, the light modulation device 400G, and the light modulation device 400B. The plurality of second lenses 132 are arranged in a matrix in a plane orthogonal to the illumination optical axis 100ax.

The polarization convertor 140 converts each of the plurality of partial light fluxes divided by the first lens array 120 into a linearly polarized light having an aligned polarization direction.

The superimposing lens 150 condenses the partial light fluxes emitted from the polarization convertor 140, and superimposes the partial light fluxes on each other in the vicinity of the image forming region of each of the light modulation device 400R, the light modulation device 400G, and the light modulation device 400B. The first lens array 120, the second lens array 130, and the superimposing lens 150 form an integrator optical system that makes an in-plane light intensity distribution of the light from the wavelength convertor 100 uniform.

The color separation light guiding optical system 503 includes dichroic mirrors 210, 220, reflection mirrors 230, 240, and 250, and relay lenses 260, 270. The color separation light guiding optical system 503 separates the white light W obtained from the first illumination device 501 and the second illumination device 502 into a red light R, a green light G, and the blue light B, and guides the red light R, the green light G, and the blue light B to the corresponding light modulation devices 400R, 400G, and 400B.

A field lens 300R is disposed between the color separation light guiding optical system 503 and the light modulation device 400R. A field lens 300G is disposed between the color separation light guiding optical system 503 and the light modulation device 400G. A field lens 300B is disposed between the color separation light guiding optical system 503 and the light modulation device 400B.

A red light component is transmitted through the dichroic mirror 210, and a green light component and a blue light component are reflected by the dichroic mirror 210. The green light component is reflected by the dichroic mirror 220, and the blue light component is transmitted through the dichroic mirror 220. The reflection mirror 230 reflects the red light component. The reflection mirror 240 and the reflection mirror 250 reflect the blue light component.

The red light transmitted through the dichroic mirror 210 is reflected by the reflection mirror 230, is transmitted through the field lens 300R, and is incident on the image forming region of the light modulation device 400R for a red light. The green light reflected by the dichroic mirror 210 is further reflected by the dichroic mirror 220, is transmitted through the field lens 300G, and is incident on the image forming region of the light modulation device 400G for a green light. The blue light transmitted through the dichroic mirror 220 passes through the relay lens 260, the reflection mirror 240 on the incident side, the relay lens 270, the reflection mirror 250 on the emission side, and the field lens 300B, and is incident on the image forming region of the light modulation device 400B for a blue light.

The light modulation devices 400R, 400G, and 400B modulate an incident color light according to image information to form an image light. Each of the light modulation devices 400R, 400G, and 400B includes a liquid crystal light valve. Although not shown, an incident side polarization plate is disposed on a light incident side of each of the light modulation devices 400R, 400G, and 400B. An emission side polarization plate is disposed on a light emission side of each of the light modulation devices 400R, 400G, and 400B.

The photosynthetic element 600 synthesizes image lights emitted from the light modulation devices 400R, 400G, and 400B to form a full-color image light. The photosynthetic element 600 is implemented by a cross dichroic prism having a substantially square shape in a plan view in which four right-angled prisms are bonded. A dielectric multilayer film is formed at a substantially X-shaped interface in which the right-angled prisms are bonded together.

The image light emitted from the photosynthetic element 600 is enlarged and projected by the projection optical device 700 to form an image on a screen SCR. That is, the projection optical device 700 projects a light modulated by the light modulation devices 400R, 400G, and 400B. The projection optical device 700 includes a plurality of projection lenses 6.

Next, the configuration of the wavelength convertor 100 will be described with reference to FIGS. 2 to 6.

As shown in FIG. 2, the wavelength convertor 100 includes a substrate 10 and the wavelength conversion layer 20 disposed on the substrate 10.

Specifically, as shown in FIG. 3, in the wavelength convertor 100, the substrate 10 and the wavelength conversion layer 20 are bonded to each other via a bonding material 30. The wavelength convertor 100 of the present embodiment emits the fluorescence Y toward the same side as the side on which the excitation light E is incident. That is, the wavelength convertor 100 is a reflective wavelength convertor.

The substrate 10 includes a substrate body 11, a nickel (Ni) layer 12a as a first metal film disposed on the substrate body 11, and a gold (Au) layer 12b as a second metal film disposed on the Ni layer 12a. Ni is a first substance and Au is a second substance. In addition, the Ni layer 12a and the Au layer 12b are collectively referred to as a protective film 12. In addition, the substrate body 11 is also referred to as a substrate. The substrate body 11 is made of a material containing a metal, and is made of, for example, a metal plate material having high thermal conductivity such as copper. The Ni layer 12a and the Au layer 12b are formed by, for example, an electroless plating method.

The wavelength conversion layer 20 includes, for example, a reflective multilayer film 21 and a phosphor layer 22 disposed on the reflective multilayer film 21. The reflective multilayer film 21 is made of a metal having a high reflectance such as silver (Ag). The reflective multilayer film 21 reflects the excitation light E from the phosphor layer 22 as the fluorescence Y.

The phosphor layer 22 includes a ceramic phosphor that wavelength-converts the excitation light E into the fluorescence Y of a second wavelength band different from the first wavelength band of the excitation light E. That is, the phosphor layer 22 wavelength-converts the excitation light E into the fluorescence Y of the second wavelength band different from the first wavelength band. The second wavelength band is, for example, 490 nm to 750 nm, and the fluorescence Y is a yellow light including a red light component and a green light component. The phosphor layer 22 may contain a single crystal phosphor.

The phosphor layer 22 includes, for example, an yttrium-aluminum-garnet (YAG) phosphor. When taking YAG: Ce, which contains cerium (Ce) as an activator, as an example, a material in which raw material powders containing constituent elements such as Y₂O₃, Al₂O₃, and CeO, are mixed and subjected to a solid-phase reaction, Y—Al—O amorphous particles obtained by a wet method such as a coprecipitation method or a Solgel method, YAG particles obtained by a vapor phase method such as a spray drying method, a flame thermal decomposition method, or a thermal plasma method and the like can be used as the phosphor layer 22.

When the excitation light E is incident on the wavelength conversion layer 20, heat 101 (see FIG. 3) is generated in the phosphor layer 22. In the present embodiment, a sintered nano silver (Ag) particle material is used as the bonding material 30, such that the heat 101 generated in the phosphor layer 22 is radiated from the substrate 10 via the bonding material 30.

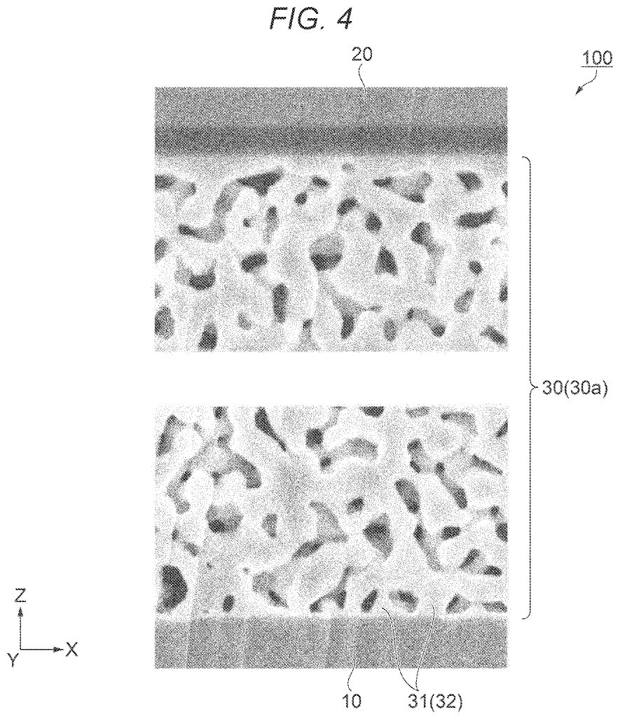

Next, a configuration of the bonding material 30 will be described with reference to FIGS. 4 to 6.

As shown in FIG. 4, in the wavelength convertor 100, the substrate 10 and the wavelength conversion layer 20 are bonded to each other via the bonding material 30. The bonding material 30 is, for example, a sintered body 30a having a porous structure in which metal fine particles 32 are fused and densified by sintering at a relatively low temperature of about 200° C. In the present embodiment, portions where the metal fine particles 32 are fused are referred to as sintered portions 31.

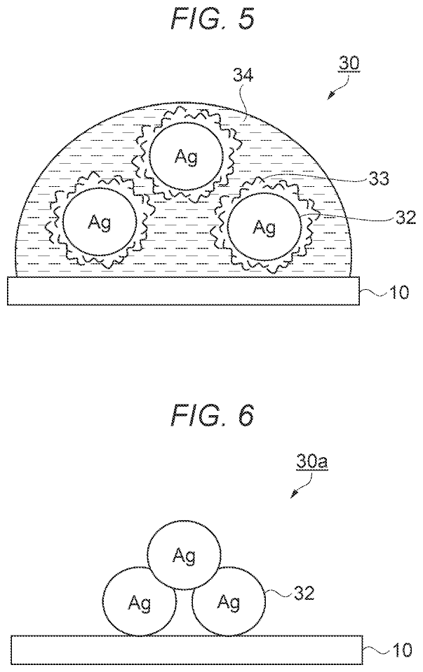

As shown in FIG. 5, the bonding material 30 includes the metal fine particles 32 made of silver (Ag), surface stabilizers 33 serving as a first film disposed on surfaces of the metal fine particles 32, and an organic solvent 34, and is applied onto the substrate 10. In other words, in the bonding material 30, the metal fine particles 32 to which the surface stabilizers 33 are applied are dispersed in the organic solvent 34. The bonding material 30 is also referred to as a sintered nano silver (Ag) paste. Examples of the organic solvent 34 include alcohols that can evaporate at a relatively low temperature of about 200° C.

As shown in FIG. 6, when the bonding material 30 is heated, the organic solvent 34 is volatilized, and the surface stabilizers 33 are decomposed, such that the bonding material 30 becomes the sintered body 30a in which the surfaces of the metal fine particles 32 appear. The surfaces of the metal fine particles 32, which are minute and not oxidized, react with a significant activity. Outermost surfaces of the active metal fine particles 32 are melted at a temperature equal to or lower than a melting point of the metal fine particles 32, and the sintered body 30a in which contact portions of the metal fine particles 32 are fused is obtained. The surfaces of the melted metal fine particles 32 are wet-diffused and bonded to a surface of the substrate 10. After the sintering, the sintered body 30a composed of only the metal fine particles 32 is obtained. The thermal conductivity of the bonding material 30, that is, the sintered body 30a is, for example, 213 W/m k.

As described above, the bonding material 30 shown in FIG. 4, that is, the sintered body 30a can sufficiently evaporate the organic solvent 34 such that the organic solvent 34 does not substantially remain in the sintered body even by a sintering treatment at a low temperature. In addition, even when the sintered body 30a having the porous structure is pressurized with a relatively low pressure, the metal fine particles 32 are easily densified and recrystallized. In addition, since the bonding material 30 has a high heat dissipation property, the wavelength convertor 100 can sufficiently function even when the same portion of the wavelength convertor 100 is continuously irradiated with the excitation light E.

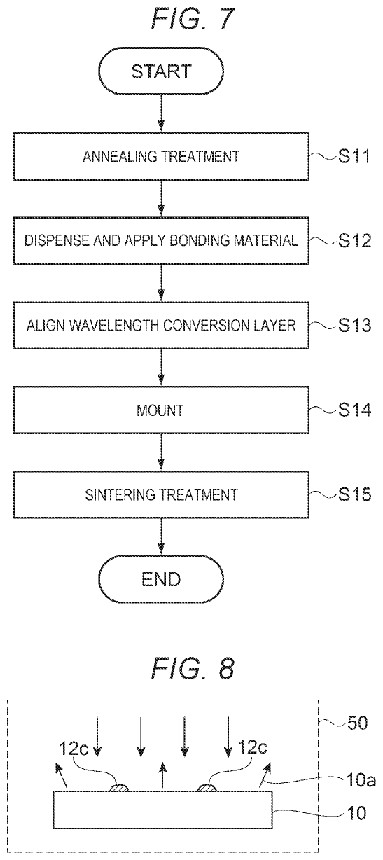

Next, a method of manufacturing the wavelength convertor 100 of a first embodiment will be described with reference to FIGS. 7 to 11.

As shown in FIG. 7, in step S11, the substrate 10 is subjected to a baking treatment. Specifically, the substrate 10 having a first surface 11a, the wavelength conversion layer 20 that modulates a light of the first wavelength band into a light of the second wavelength band different from the light of the first wavelength band, and the bonding material 30 containing the metal fine particles 32 and the surface stabilizers 33 that are formed at the surfaces of the metal fine particles 32 and decomposed by oxygen are prepared in advance.

The substrate 10 includes the Ni layer 12a and the Au layer 12b that form the protective film 12 for protecting the first surface 11a. Specifically, the Ni layer 12a and the Au layer 12b are formed at the first surface 11a of the substrate body 11 by the electroless plating method while generating a gas 10a composed of hydrogen. A thickness of the Ni layer 12a is, for example, 3 μm. A thickness of the Au layer 12b is, for example, 0.06 μm.

Next, as shown in FIG. 8, in a heating treatment furnace 50, the substrate 10 including the protective film 12 is subjected to the baking treatment, that is, a heating treatment. Treatment conditions for the baking treatment is, for example, heating to 200° C. for 1 hour in an air atmosphere. Accordingly, in a step of forming the protective film 12, the gas 10a occluded by the protective film 12 or the substrate body 11 can be released from the protective film 12 or the substrate body 11.

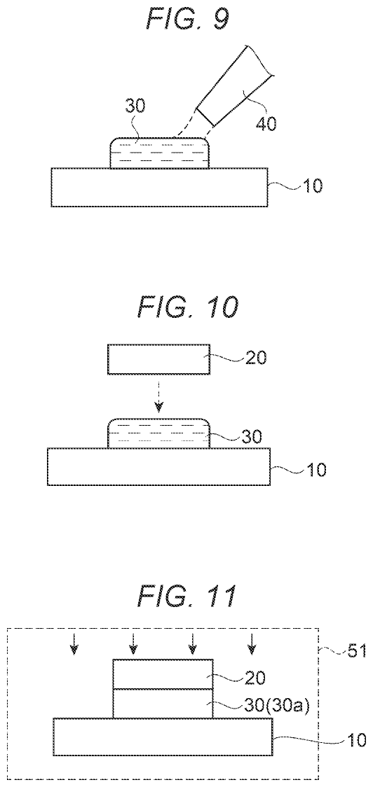

In step S12, the bonding material 30 containing the metal fine particles 32 is applied onto the substrate 10 using a dispenser 40. Specifically, as shown in FIG. 9, the bonding material 30 (see FIG. 5) is applied onto the substrate 10 subjected to the baking treatment by using the dispenser 40. The disclosure is not limited to the dispenser 40, and for example, mask printing, screen printing, an inkjet method, and the like may be used.

In step S13, the wavelength conversion layer 20 is aligned. Specifically, as shown in FIG. 10, a position of the wavelength conversion layer 20 is aligned with a position of the substrate 10 as a reference.

In step S14, the wavelength conversion layer 20 is mounted. Specifically, as shown in FIG. 10, the wavelength conversion layer 20 is mounted on the aligned substrate 10. That is, the wavelength conversion layer 20 is brought into contact with the bonding material 30 on the substrate 10.

In step S15, the substrate 10, the wavelength conversion layer 20, and the bonding material 30 are subjected to the sintering treatment. Specifically, as shown in FIG. 11, for example, the substrate 10 including the wavelength conversion layer 20 and the bonding material 30 is placed in a sintering furnace 51, is heated at a relatively low temperature of about 200° C. for a short time, for example, for 60 minutes, and is subjected to the sintering treatment without pressure. Accordingly, the metal fine particles 32 contained in the bonding material 30 are sintered, and the substrate 10 and the wavelength conversion layer 20 are bonded by the bonding material 30. The sintering treatment is not limited to being performed in the sintering furnace 51, and may be performed using a known method such as a hot plate or an oven.

As described above, the organic solvent 34 is evaporated from the bonding material 30, the surface stabilizers 33 formed at the surfaces of the metal fine particles 32 are decomposed by oxygen, the adjacent metal fine particles 32 are fused to each other while leaving slight gaps therebetween, and the sintered body 30a having the porous structure in which the metal fine particles 32 are closely contacted with each other is formed. In addition, at an interface between the substrate 10 and the bonding material 30, the metal fine particles 32 are densified and bonded to the substrate 10. Further, at an interface between the wavelength conversion layer 20 and the bonding material 30, the metal fine particles 32 are densified and bonded to the wavelength conversion layer 20.

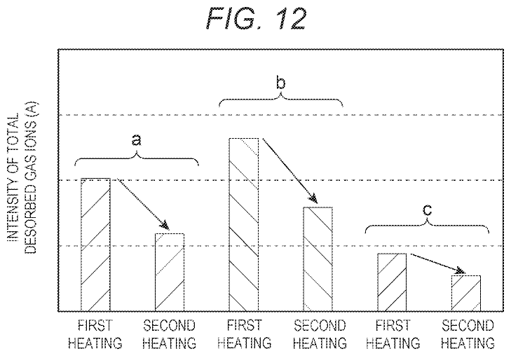

Next, an intensity of the gas (gas ions) generated when the substrate 10 and the bonding material 30 are subjected to the heating treatment will be described with reference to FIG. 12.

In a graph shown in FIG. 12, a horizontal axis represents states of first heating and second heating of a sample a, a sample b, and a sample c. A vertical axis represents an intensity of total desorbed gas ions for each sample, and an amount of the generated gas increases toward the upper side.

Each sample includes at least the substrate 10 mainly composed of copper (Cu). In addition, the graph shown in FIG. 12 is obtained by analyzing the behavior during heating by a temperature rising desorption gas analysis method (TPD).

In the sample a, the gold (Au) layer 12b having a thickness of 0.05 μm is formed at the substrate body 11 by an electrolytic plating method. In the sample b, the Au layer 12b having a thickness of 0.5 μm is formed at the substrate body 11 by the electrolytic plating method. In the sample c, the Au layer 12b having a thickness of 0.05 μm is formed at the substrate body 11 by the electroless plating method.

Examples of the desorbed gas include hydrogen (H), hydrogen molecules (H₂), a carbon (C)-based gas derived from organic contaminants, and water (H₂O).

As shown in FIG. 12, in each sample, the amount of the generated gas is smaller in the second heating than in the first heating. In addition, the amount of the generated gas is smaller in the sample c, in which the Au layer 12b is formed by the electroless plating method, than in the samples a, b in which the Au layer 12b is formed by the electrolytic plating method. In addition, the amount of the gas of the sample b, in which the thickness of the Au layer 12b is thick, is larger than the amount of the gas of the samples a, c in which the thickness of the Au layer 12b is thin.

The first heating corresponds to the baking treatment of the present embodiment. The second heating corresponds to the sintering treatment of the present embodiment. In view of this, by performing the baking treatment before performing the sintering treatment, the amount of the gas ions generated in the sintering treatment can be reduced. In other words, since the gas 10a made of hydrogen and the like is released from the substrate body 11 before bonding, the surface stabilizers 33 can be decomposed without being hindered due to hydrogen during bonding. Therefore, in a step of bonding, a plurality of metal fine particles 32 remaining after decomposition are metal-sintered while using a large amount of oxygen.

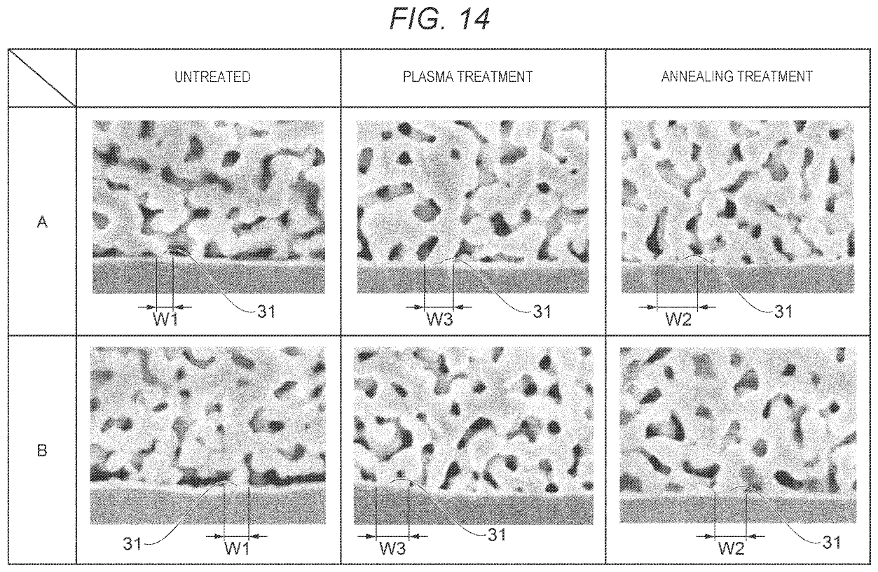

Next, with reference to FIGS. 14 to 16, a result of comparing bonding states of the bonding material 30 between a case where the baking treatment is not performed and a case where the baking treatment is performed will be described.

FIG. 14 shows a state after sintering of the bonding material 30 in two lots A, B, and compares widths of the sintered portions 31 (referred to as “necks”) of the fused metal fine particles 32. In the present embodiment, in the two lots A, B, a case where the baking treatment before the sintering treatment is not performed is compared with a case where the baking treatment is performed.

As shown in FIG. 14, it can be seen that a thickness W2 of the neck when the baking treatment is performed is larger than a thickness W1 of the neck when the baking treatment is not performed. In addition, it can be seen that both of the two lots A, B have such a tendency.

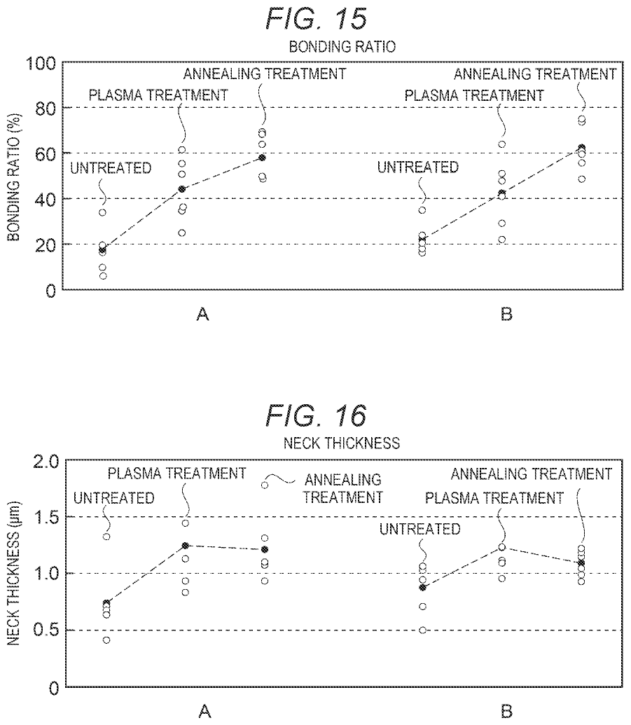

In a graph shown in FIG. 15, the horizontal axis represents states of the two lots A, B, and the vertical axis represents a bonding ratio. The bonding ratio of the vertical axis is higher toward the upper side, in other words, a bonding strength is higher. As shown in FIG. 15, in each of the two lots A, B, the bonding ratio when the baking treatment is performed is higher than the bonding ratio when the baking treatment is not performed.

In a graph shown in FIG. 16, the horizontal axis represents the states of the two lots A, B, and the vertical axis represents the thickness of the neck. The thickness of the neck on the vertical axis increases toward the upper side, in other words, the bonding strength is higher. As shown in FIG. 16, in each of the two lots A, B, the thickness of the neck when the baking treatment is performed is larger than the thickness of the neck when the baking treatment is not performed.

From the results shown in FIGS. 14 to 16, it can be seen that a large amount of oxygen is required in order to decompose the surface stabilizers 33 formed at the surfaces of the metal fine particles 32 contained in the bonding material 30 and promote the fusion of the metal fine particles 32.

As described above, the method of manufacturing the wavelength convertor 100 of the present embodiment includes: preparing the substrate body 11 having the first surface 11a; preparing the wavelength conversion layer 20 that modulates the light of the first wavelength band into the light of the second wavelength band different from the light of the first wavelength band; preparing the bonding material 30 including the metal fine particles 32 and the surface stabilizers 33 formed at the surfaces of the metal fine particles 32 and decomposed by oxygen; forming the protective film 12 protecting the first surface 11a while generating the gas 10a containing hydrogen; releasing, from the protective film 12 or the substrate body 11, the gas 10a occluded by the protective film 12 or the substrate body 11 in the forming of the protective film 12; and bonding the substrate 10 and the wavelength conversion layer 20 via the bonding material 30 by metal sintering.

According to this method, since the gas 10a made of hydrogen is released from the protective film 12 or the substrate body 11 before bonding, the surface stabilizers 33 can be decomposed without being hindered due to hydrogen during bonding. Therefore, in the step of bonding, the metal fine particles 32 remaining after the decomposition are metal-sintered while using a large amount of oxygen, and the bonding strength between the substrate 10 and the wavelength conversion layer 20 can be improved. Accordingly, the wavelength conversion layer 20 can be prevented from being peeled off from the substrate 10.

In addition, in the method of manufacturing the wavelength convertor 100 of the present embodiment, in the step of releasing, the substrate 10 including the protective film 12 is preferably subjected to the baking treatment. According to this method, since the substrate 10 including the protective film 12 is subjected to the baking treatment (heating treatment), hydrogen generated at the time of forming the protective film 12 can be released from the substrate 10 including the protective film 12.

In addition, in the method of manufacturing the wavelength convertor 100 of the present embodiment, the material of the protective film 12 is preferably nickel (Ni) and gold (Au). According to this method, since nickel is formed at the surface of the substrate body 11, the corrosion resistance of the substrate body 11 can be improved. In addition, since gold is laminated on the surface of nickel, the thermal conductivity can be improved.

In addition, in the method of manufacturing the wavelength convertor 100 of the present embodiment, in the step of forming the protective film 12, the protective film 12 is preferably formed at the first surface 11a of the substrate body 11 by using the electroless plating method. According to this method, since the protective film 12 is formed by the electroless plating method, it is possible to reduce the amount of the gas 10a made of hydrogen generated at the time of metal sintering. Therefore, it is possible to prevent the inhibition of the decomposition of the surface stabilizer 33 due to hydrogen, and it is possible to efficiently perform the bonding between the substrate 10 including the protective film 12 and the wavelength conversion layer 20.

In addition, in the method of manufacturing the wavelength convertor 100 of the present embodiment, the metal fine particles 32 are preferably nano silver particles. According to this method, the substrate 10 and the wavelength conversion layer 20 can be bonded to each other by the bonding material 30 having high thermal conductivity and being easily subjected to metal sintering.

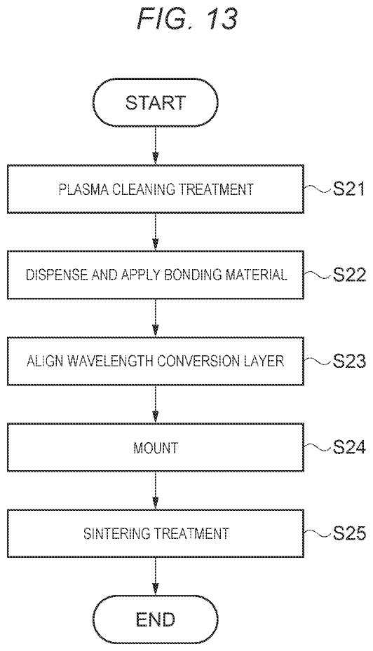

Next, a method of manufacturing the wavelength convertor 100 of a second embodiment will be described with reference to FIG. 13.

As shown in FIG. 13, the method of manufacturing the wavelength convertor 100 of the second embodiment is different from that of the first embodiment in that a plasma cleaning treatment is performed instead of the baking treatment before the sintering treatment. Other configurations are substantially the same. Therefore, in the second embodiment, portions different from those of the first embodiment will be described in detail, and description of the other overlapping portions will be appropriately omitted.

As shown in FIG. 13, in step S21, the substrate is subjected to the plasma cleaning treatment. Specifically, for example, as shown in FIG. 8, a foreign matter (for example, a substance 12c, see FIG. 8) attached to the surface of the substrate 10 including the protective film 12 and the surface of the protective film 12 are subjected to the plasma cleaning. The foreign matter is, for example, an organic substance containing carbon (C), nitrogen (N), oxygen (O), and the like. In addition, the plasma cleaning may be, for example, plasma reactive ion etching (RIE).

Hereinafter, steps S22 to S25 are performed in the same manner as steps S12 to S15 of the first embodiment.

As described above, by performing the plasma cleaning treatment on the substrate 10 before the sintering treatment, it is possible to prevent a decrease in the bonding strength due to the substance 12c, and it is possible to improve the bonding strength between the substrate 10 and the wavelength conversion layer 20. Accordingly, the wavelength conversion layer 20 can be prevented from being peeled off from the substrate 10.

Next, with reference to FIGS. 14 to 16, a result of comparing bonding states of the bonding material 30 between a case where the plasma cleaning treatment is not performed and a case where the plasma cleaning treatment is performed will be described.

As shown in FIG. 14, it can be seen that a thickness W3 of the neck when the plasma treatment is performed is larger than the thickness W1 of the neck when the plasma treatment is not performed. In addition, it can be seen that both of the two lots A, B have such a tendency.

As shown in FIG. 15, in each of the two lots A, B, the bonding ratio when the plasma treatment is performed is higher than the bonding ratio when the plasma treatment is not performed.

As shown in FIG. 16, in each of the two lots A, B, the thickness of the neck when the plasma treatment is performed is larger than the thickness of the neck when the plasma treatment is not performed.

From the results shown in FIGS. 14 to 16, it is effective to remove the substance 12c attached to the surface of the substrate 10 by the plasma cleaning.

As described above, the method of manufacturing the wavelength convertor 100 of the second embodiment includes: preparing the substrate 10 having the first surface 11a and the protective film 12 containing Ni for protecting the first surface 11a; preparing the wavelength conversion layer 20 that modulates the light of the first wavelength band into the light of the second wavelength band different from the light of the first wavelength band; preparing the bonding material 30 containing the metal fine particles 32; removing, by the plasma cleaning, the substance 12c different from Ni attached to the surface of the protective film 12 opposite to the substrate body 11; and bonding the substrate 10 including the protective film 12 and the wavelength conversion layer 20 via the bonding material 30 by metal sintering.

According to this method, since the substance 12c attached to the surface of the protective film 12 is removed by the plasma cleaning before bonding, it is possible to prevent a decrease in the bonding strength due to the substance 12c, and it is possible to improve the bonding strength between the substrate 10 and the wavelength conversion layer 20. Accordingly, the wavelength conversion layer 20 can be prevented from being peeled off from the substrate 10.

Hereinafter, a modification of the above-described embodiment will be described.

The disclosure is not limited to the above-described embodiment in which either the baking treatment or the plasma treatment is performed before the sintering treatment is performed, for example, the plasma cleaning treatment may be performed after the baking treatment.

As described above, in the method of manufacturing the wavelength convertor 100 of the present embodiment, it is preferable that the protective film 12 includes the Ni layer 12a formed at the first surface 11a and the Au layer 12b laminated on the Ni layer 12a, in the step of releasing, Ni of the Ni layer 12a is deposited and oxidized on the surface of the Au layer 12b to form the substance 12c (for example, an oxide film containing Ni), and after the step of releasing, the plasma cleaning treatment of removing the substance 12c on the surface of the protective film 12 is performed.

According to this method, since the plasma cleaning treatment is performed after the baking treatment, even when the substance 12c and the like are deposited on the surface of the protective film 12 in the baking treatment or the substance 12c is attached to the surface of the protective film 12 in the plating treatment, the substance 12c can be removed by the plasma cleaning treatment, and the bonding strength between the substrate 10 and the wavelength conversion layer 20 can be improved.

In addition, the metal fine particles 32 are not limited to silver (Ag), and may be composed of, for example, particles made of one or more of gold (Au), platinum (Pt), and palladium (Pd).

In addition, as described above, the disclosure is not limited to the fixed type wavelength convertor 100, and may be applied to a rotary type wavelength convertor including a motor.

What is claimed is:

1. A method of manufacturing a wavelength convertor, comprising:
preparing a substrate having a first surface;
preparing a wavelength conversion layer that converts a light of a first wavelength band into a light of a second wavelength band different from the light of the first wavelength band;
preparing a bonding material including a metal fine particle and a first film formed at a surface of the metal fine particle and decomposed by oxygen;
forming a protective film protecting the first surface while the protective film generates a gas containing hydrogen;
releasing, from one of the protective film and the substrate, the gas occluded by the one of the protective film and the substrate in the forming of the protective film; and
bonding the substrate and the wavelength conversion layer via the bonding material by metal sintering.

2. The method of manufacturing a wavelength convertor according to claim 1, wherein
the releasing includes a baking treatment performed on the substrate including the protective film.

3. The method of manufacturing a wavelength convertor according to claim 1, wherein
the protective film includes
a first metal film containing a first substance which is a metal formed at the first surface, and
a second metal film containing a second substance which is a metal laminated on the first metal film,
in the releasing, the first substance of the first metal film is deposited and oxidized on a surface of the second metal film to form an oxide film, and
after the releasing, a plasma cleaning treatment for removing the oxide film on a surface of the protective film is performed.

4. The method of manufacturing a wavelength convertor according to claim 3, wherein
the first substance is nickel (Ni), and
the second substance is gold (Au).

5. The method of manufacturing a wavelength convertor according to claim 1, wherein
the forming of the protective film includes forming the protective film on the first surface of the substrate by using an electroless plating method.

6. A method of manufacturing a wavelength convertor, comprising:
preparing a substrate having a first surface and a protective film containing a first substance that protects the first surface;
preparing a wavelength conversion layer that converts a light of a first wavelength band into a light of a second wavelength band different from the light of the first wavelength band;
preparing a bonding material containing a metal fine particle;
removing, by plasma cleaning, foreign matter different from the first substance attached to a surface of the protective film opposite to the substrate; and
bonding the wavelength conversion layer and the substrate including the protective film via the bonding material by metal sintering.

7. The method of manufacturing a wavelength convertor according to claim 1, wherein
the metal fine particle is a nano silver particle.
